(19) United States
(12) Patent Application Publication
(10) Pub. No.: US 2003/0132496 A1
(43) Pub. Date: Jul. 17, 2003

(54) Compound semiconductor device, method for producing thereof and high frequency module using thereof

(75) Inventors: Akihisa Terano, Hachioji (JP); Hiroshi Ohta, Kawasaki (JP); Kiyoshi Ouchi, Kodaira (JP); Tomoyoshi Mishima, Shiki (JP)

Correspondence Address: Stanley P. Fisher, Reed Smith LLP, Suite 1400, 3110 Fairview Park Drive, Falls Church, VA, 22042-4503, US

(73) Assignee: Hitachi, Ltd.

(21) Appl. No.: 10/298,655

(22) Filed: Nov. 19, 2002

(30) Foreign Application Priority Data
Jan. 15, 2002 (JP) 2002-005553

(51) Int. Cl. H01L 31/00; H01L 27/095; H01L 29/47; H01L 21/28

(52) U.S. Cl. 257/449; 438/570; 438/572; 257/471; 257/472

(57) ABSTRACT

On an In-containing compound semiconductor are sequentially formed Zn (p-type dopant-containing layer), Ta (high-melting metal layer) and a low-resistance conductor layer in this order as a Schottky electrode, and the resulting assemblage is annealed to diffuse Zn into the semiconductor to thereby convert the surface of the semiconductor layer only in a region in contact with the Schottky electrode metal into a p-type layer. The p-type dopant-containing layer can be, instead of Zn, a compound between Zn and an element constituting the In-containing compound semiconductor or a Zn—Ta alloy. The high-melting metal layer can be, instead of Ta, an intermetallic compound between Ta and an element constituting the In-containing compound semiconductor or a Zn—Ta alloy.

### BACKGROUND OF THE INVENTION

1. Field of the Invention

The present invention relates to a compound semiconductor device having an In-containing compound semiconductor layer and a Schottky electrode arranged thereon, a method for producing the compound semiconductor device, and a high frequency module including the compound semiconductor device. More specifically, it relates to a compound semiconductor device that is useful as an In-containing compound semiconductor device having a gate electrode with a high Schottky barrier φb, a method for producing the same, and a high frequency module using the same.

2. Description of the Related Art

Certain high electron mobility transistors (HEMTs) are known as a type of field effect transistors using GaAs, InP, and other compound semiconductors.

The HEMTs have a nondoped channel layer and an electron supply layer having a band gap larger than that of the channel layer and being doped with a dopant. They enable transportation of a two-dimensional electron gas in the nondoped channel layer, which two-dimensional electron gas is formed as a result of hetero junction between the channel layer and the electron supply layer. Thus, they can yield a higher electron mobility than regular field effect transistors having a doped channel layer.

For example, AlGaAs/GaAs, AlGaAs/InGaAs, and other high electron mobility transistors (HEMTs) have been developed, and certain power modules and high frequency modules using these HEMTs have already been used in practice. To achieve higher performance and to be used in higher frequency regions, InAlAs/InGaAs HEMTs having higher electron mobility have been developed.

These HEMTs use a Schottky contact gate. A leak current upon the application of a reverse bias on the gate electrode must be reduced to produce high-withstand-voltage HEMTs.

The conventional AlGaAs/GaAs or AlGaAs/InGaAs HEMTs have a gate electrode arranged on an AlGaAs layer having a large band gap, can thereby yield a relatively high Schottky barrier φb and can reduce the leak current by combining a metal having a high work function, such as Pt, with the semiconductor.

The InAlAs/InGaAs HEMTs have a gate electrode arranged on InAlAs that has a relatively large band gap among semiconductor materials capable of yielding lattice matching with InP. However, InAlAs has a band gap smaller than AlGaAs that can yield lattice matching with GaAs, and when the same metal layer is formed on AlGaAs and InAlAs, respectively, the resulting device having the metal layer on InAlAs shows a significantly lower Schottky barrier φb than one having the metal layer on AlGaAs, thus leading to an increased leak current.

As a possible solution to these problems, for example, Japanese Unexamined Patent Application Publication No. 05-166844 discloses a method for producing a Schottky electrode having a high Schottky barrier φb with respect to InAlAs and other In-containing compound semiconductor layers. In this method, the outermost surface of an InAlAs layer in a Schottky contact formation area of a gate region of an InAlAs/InGaAs HEMT is subjected to, for example, dopant diffusion and is converted into a p-type layer to thereby increase a surface potential; and a Ti/Pt/Au multilayer film to serve as a gate electrode is formed on the p-type layer to thereby ensure a high Schottky barrier φb.

The publication also mentions that the InAlAs layer is converted into a p-type layer by (1) a process of exposing the InAlAs layer to an atmosphere containing an element serving as a p-type dopant to thereby form a thin p-type layer in the InAlAs layer; or (2) a process of forming a layer of an electrode material containing a p-type dopant at an early stage in the formation of a Schottky gate electrode. The publication mentions that an InAlAs/InGaAs high electron mobility transistor having a Schottky gate electrode with a high Schottky barrier is obtained by this technique with excellent process controllability.

To verify whether or not the conventional Schottky electrode can yield a high Schottky barrier φb in an InAlAs/InGaAs high electron mobility transistor (HEMT), the present inventors have made the following test. Specifically, a vertical Schottky diode was prepared by forming a 5-nm Zn/50-nm Ti/50-nm Pt/300-nm Au multilayer electrode on an InAlAs layer on a n-type InP substrate having a carrier concentration of 1×10¹⁷ cm⁻³ and forming an ohmic electrode on the opposite side of the substrate. The relationship between the Schottky barrier φb and the annealing temperature of the Schottky diode was determined.

The Schottky electrode used in the test was prepared according to the process (2) of the conventional technique. The Schottky barrier φb of the prepared Schottky electrode is less than 0.5 eV before annealing, increases by annealing and reaches the maximum of 0.61 eV after annealing at 300° C. as shown as Characteristic Line 2 in FIG. 1.

However, the Schottky barrier φb is at the same level as a Pt/Ti/Pt/Au electrode, 0.60 eV, after annealing at 300° C. The Pt/Ti/Pt/Au electrode was prepared according to the same procedure as above, except that elementary Pt was used in Schottky contact. The results of the Pt/Ti/Pt/Au electrode is shown as Characteristic Line 3 in FIG. 1. These results show that the conventional Schottky electrode cannot yield a significantly increased Schottky barrier φb.

In addition, the conventional Schottky electrode does not exhibit an increased Schottky barrier φb even by annealing at a higher temperature, 350° C.

The conventional Zn/Ti/Pt/Au Schottky electrode cannot yield excellent Schottky properties and cannot significantly reduce a reverse gate leak current in the InAlAs/InGaAs HEMT. Accordingly, the conventional technique fails to prepare high withstand-voltage InAlAs/InGaAs HEMTs.

### SUMMARY OF THE INVENTION

Accordingly, an object of the present invention is to solve the above problems of conventional techniques and to provide a compound semiconductor device having a Schottky electrode that can yield a high Schottky barrier φb with respect to an In-containing compound semiconductor layer, a method for producing the compound semiconductor device, and a high frequency module using the compound semiconductor device.

The above object can be achieved by forming a thin layer of a p-type dopant-containing layer on an In-containing compound semiconductor, such as InAlAs, a high-melting metal layer on the p-type dopant-containing layer, and a low-resistance conductor layer on the high-melting metal layer in this order to yield a Schottky electrode; and annealing the Schottky electrode.

The p-type dopant-containing layer is preferably a film including an electrode material selected from Zn, intermetallic compounds between Zn and an element constituting the In-containing compound semiconductor, and Zn—Ta alloys and preferably has a thickness from 1 nm to 50 nm.

The high-melting metal layer is preferably a film including an electrode material selected from Ta, intermetallic compounds between Ta and an element constituting the In-containing compound semiconductor, and Zn—Ta alloys and preferably has a thickness from 1 nm to 50 nm

The low-resistance conductor layer is preferably one selected from a Au single-layer film; an Al single-layer film; Ti/Au film, Ti/Pt/Au film, Pt/Ti/Pt/Au film, Mo/Ti/Pt/Au film, and other metallic multilayer films having Au as the uppermost layer; and Ti/Al film, Mo/Al film, and other metallic multilayer films having Al as the uppermost layer.

The present invention can achieve the above objects and can yield a compound semiconductor device having a Schottky electrode having satisfactory Schottky properties with respect to an In-containing compound semiconductor layer, and a high frequency module using the compound semiconductor device with good repeatability.

Further objects, features and advantages of the present invention will become apparent from the following description of the preferred embodiments with reference to the attached drawings.

### BRIEF DESCRIPTION OF THE DRAWINGS

FIG. 1 is a graph showing the relationship between the Schottky barrier φb and the annealing temperature on a Schottky electrode according to the present invention and on the conventional Schottky electrode;

FIG. 2 is a sectional view of a compound semiconductor device as a first embodiment of the present invention;

FIG. 3 is a sectional view of a compound semiconductor device as a second embodiment of the present invention;

FIG. 4 is a sectional view of a compound semiconductor device (monolithic microwave integrated circuit: MMIC) as a third embodiment of the present invention; and

FIG. 5 is a schematic circuit diagram of a vehicle-mounted radar as a fourth embodiment of the present invention.

### DESCRIPTION OF THE PREFERRED EMBODIMENTS

Initially, a vertical Schottky diode was prepared according to the present invention. This Schottky diode comprises an InAlAs semiconductor layer and a Schottky electrode arranged on the InAlAs semiconductor layer. The Schottky electrode has a five-layer structure including a 5-nm Zn layer as a p-type dopant-containing layer being in contact with the semiconductor layer; a 30-nm Ta layer as a high-melting metal layer arranged on the p-type dopant-containing layer; a three-layer low-resistance conductor layer being arranged on the high-melting metal layer and comprising a 50-nm Ti layer, a 50-nm Pt layer and a 300-nm Au layer in this order. The relationship between the Schottky barrier φb and the annealing temperature on the vertical Schottky diode was determined.

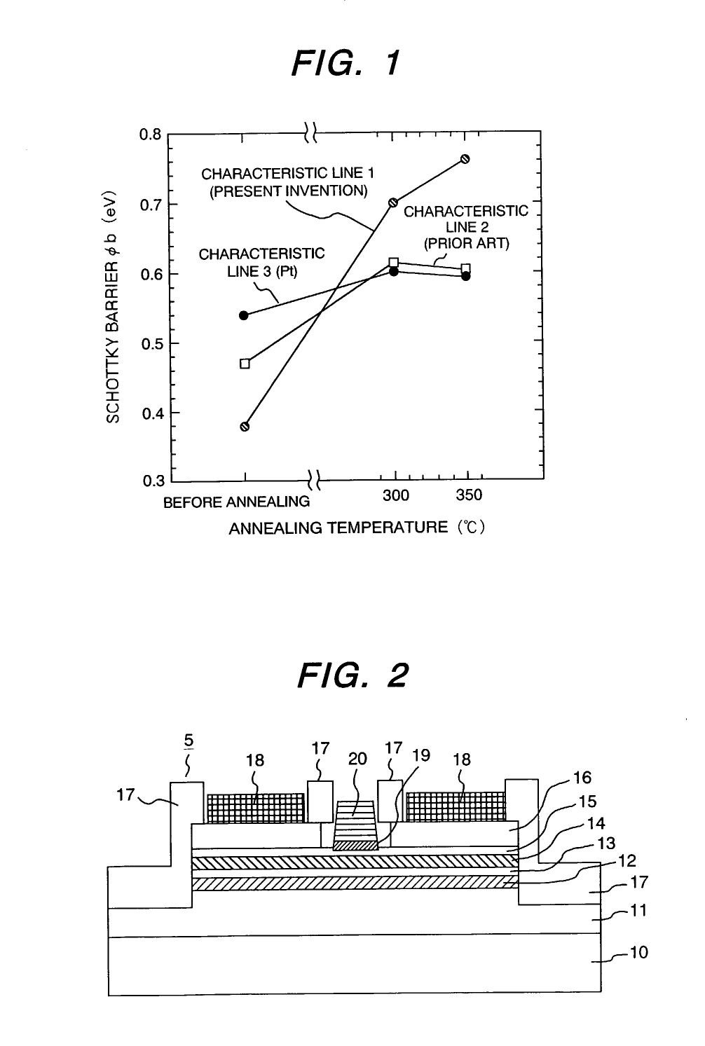

The Schottky diode according to the present invention shows a significantly high Schottky barrier φb of 0.70 eV after annealing at 300° C. (Characteristic Line 1 in FIG. 1), at which temperature the Schottky diode using the conventional Schottky electrode reaches the maximum Schottky barrier φb.

The Schottky diode of the present invention also shows a higher Schottky barrier φb of 0.76 eV after annealing at 350° C.

The difference in the Schottky barrier φb between the two Schottky electrodes is probably caused by the difference in the electrode material (metal layer) arranged on the Zn layer (p-type dopant-containing layer).

Ta has a much higher melting point, about 3000° C., than Ti, about 1700° C. In general, a metal having a higher melting point is more resistant to alloying and other intermetallic reactions.

To yield a high Schottky barrier φb, it is preferred that Zn alone in the p-type dopant-containing layer of the Schottky diode diffuses into the semiconductor layer.

However, the Auger analysis of a reaction between the electrode and semiconductor of the conventional Zn/Ti/Pt/Au electrode after annealing at 300° C. revealed that Zn diffuses not only into the semiconductor layer but also into Ti, and that Ti diffuses into a Zn-diffused region in the semiconductor.

In other words, annealing invites mutual diffusion among Ti, Zn, and the semiconductor.

These results demonstrate that the conventional Schottky electrode cannot yield a high Schottky barrier φb probably for the following reasons. Specifically, Zn diffuses into Ti to thereby reduce the amount of Zn diffusing into the semiconductor. An excessive mutual diffusion between Ti and the semiconductor in the Zn-diffused region leads to destroy of a p-type layer and a pn junction interface to be formed in the semiconductor as a result of Zn diffusion. Thus, the surface potential does not increase.

Even if the conventional Schottky electrode is prepared by converting a semiconductor layer into p-type layer and then forming a Ti/Pt/Au electrode thereon (the process (2) of the conventional technique), the formed Schottky electrode is generally subjected to a heat treatment in the production process of HEMTs and other devices. The heat treatment leads to diffusion and reaction between the p-type doped region and the Ti layer as above to thereby lower the Schottky barrier φb.

In contrast, the Auger analysis of the Schottky electrode according to the present invention revealed that Zn hardly diffuses into Ta and satisfactorily selectively diffuses into the semiconductor.

The analysis also revealed that the reaction between Ta on the Zn layer and the semiconductor in the Schottky electrode according to the present invention is much smaller than the conventional Schottky electrode in which Ti is in direct contact with the Zn layer, and that it is a nearly ideal Schottky electrode.

Specifically, the Schottky electrode according to the present invention can yield a p-type layer with higher quality than the conventional Schottky electrode and can have a sufficiently high surface potential to thereby yield a high Schottky barrier φb. In addition, the Schottky electrode can prevent excessive diffusion and reaction between the electrode metal and the semiconductor to thereby hold the Schottky barrier φb at a high level even after annealing at a higher temperature. The Schottky electrode can thereby yield high withstand-voltage HEMTs with a reduced gate leak current.

Some preferred embodiments of the present invention will be illustrated in further detail below with reference to the attached drawings.

First Embodiment

FIG. 2 is a schematic sectional view of an InAlAs/InGaAs HEMT 5 as a first embodiment of the present invention. The production method and configuration of the HEMT will be illustrated with reference to FIG. 1.

On a semi-insulating InP substrate 10 are formed a 500-nm undoped InAlAs layer 11, a 20-nm undoped InGaAs channel layer 12, a 5-nm undoped InAlAs layer 13, a 20-nm Si-doped n-type InAlAs electron supply layer 14 having a carrier concentration of 5×10¹⁸ cm⁻³, a 10-nm undoped InAlAs cover layer 15, and a 100-nm Si-doped n-type InGaAs ohmic contact layer 16 having a carrier concentration of 5×10¹⁹ cm⁻³ in this order according to a conventional molecular beam epitaxy (MBE) procedure.

The resulting assemblage is etched partway into the undoped InAlAs barrier layer 11 and thereby yields a separated “mesa” element unit.

A dielectric film 17 such as a silicon oxide film is then formed on the entire substrate.

Next, an opening is formed at a desired position on the n-type InGaAs ohmic contact layer 16 according to a conventional photolithographic procedure and dielectric film dry etching procedure. An ohmic metal is applied thereto and lifted off according to a conventional electron beam (EB) vapor deposition procedure and liftoff procedure and thereby yields a patterned electrode metal; the patterned metal is then alloyed and thereby yields source and drain electrodes 18.

Next, a gate formation area is opened according to a conventional photolithographic procedure and dielectric film etching procedure. The n-type InGaAs ohmic contact layer 16 in the gate formation area is then removed by recessing and etching to expose the undoped InAlAs cover layer 15.

On the exposed undoped InAlAs cover layer 15 are formed and lifted off a 5-nm Zn layer, a 20-nm Ta layer, a 50-nm Ti layer, a 50-nm Pt layer, and a 500-nm Au layer in this order according to a conventional EB vapor deposition procedure and lifting off procedure. The resulting assemblage is annealed at 300° C. in an atmosphere of nitrogen gas and thereby yields a gate electrode 20 having a p-type layer 19 formed by diffusion of Zn into the outermost surface of the semiconductor underneath the gate, to thereby yield the InAlAs/InGaAs HEMT 5 having a sectional structure shown in FIG. 2.

The HEMT 5 prepared according to the present embodiment comprises the InAlAs layer 15 as an In-containing compound semiconductor and the Schottky electrode (gate electrode) 20 arranged on the InAlAs layer 15. The Schottky electrode 20 comprises an assemblage of the Zn diffused layer as a thin p-type dopant-containing layer, the Ta layer as a high-melting metal layer arranged on the Zn diffused layer, and the Ti/Pt/Au layer as a low-resistance conductor layer arranged on the Ta layer.

The HEMT 5 has the gate electrode 20 formed on the InAlAs layer 15 having a band gap larger than the InP substrate 10 and can thereby yield a high Schottky barrier φb of 0.77 eV.

Second Embodiment

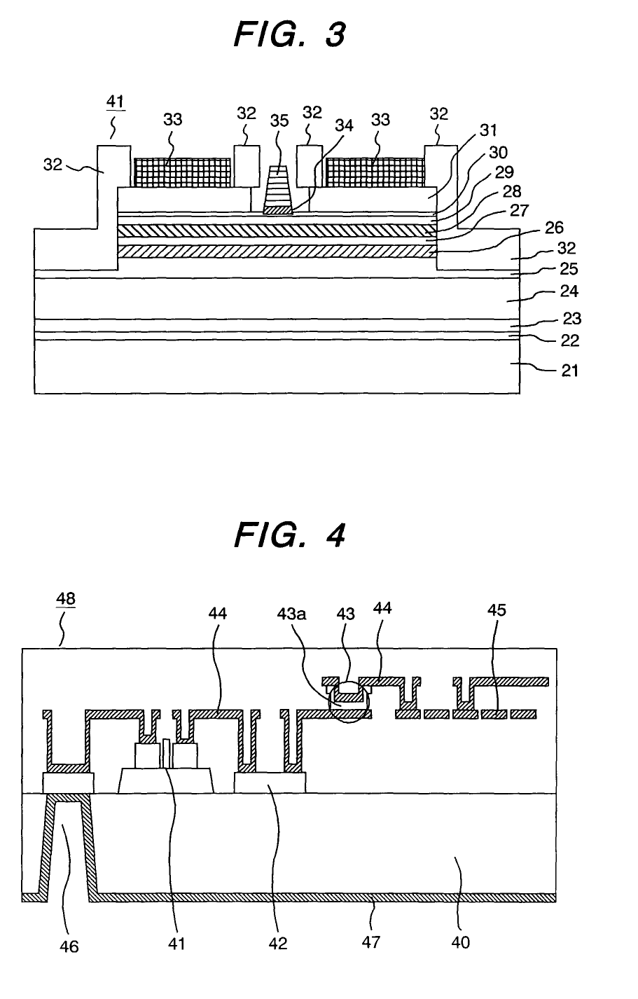

With reference to FIG. 3, a second embodiment of the present invention will be illustrated below, in which the present invention is applied to an InGaAs/InAlAs strain relaxation HEMT 41 arranged on a GaAs substrate with the interposition of a strain relaxation layer.

On a GaAs substrate 21 are formed a 30-nm undoped GaAs buffer layer 22, a 20-nm undoped AlAs buffer layer 23, a 600-nm undoped InAlAs step-graded layer 24 having a varying InAs molar ratio from 0.15 to 0.45, a 200-nm undoped InAlAs barrier layer 25, a 20-nm undoped InGaAs channel layer 26, a 2-nm undoped InAlAs layer 27, a 12-nm Si-doped n-type InAlAs carrier supply layer 28 containing 5×10¹⁸ cm⁻³ Si dopant, a 10-nm undoped InAlAs layer 29, a 5-nm undoped InP layer 30, and a 120-nm Si-doped n-type InGaAs ohmic contact layer 31 containing 5×10¹⁹ cm⁻³ Si dopant in this order according to an epitaxial growth procedure.

The resulting assemblage is etched partway into the undoped InAlAs barrier layer 25 and thereby yields a separated “mesa” element unit, and a dielectric film 32 such as a silicon oxide film is formed on the entire substrate.

Next, an opening is formed at a desired position on the n-type InGaAs ohmic contact layer 31 according to a conventional photolithographic procedure and dielectric film dry etching procedure. An ohmic metal is applied thereto and lifted off according to a conventional electron beam (EB) vapor deposition procedure and liftoff procedure and thereby yields a patterned electrode metal; the patterned metal is then alloyed and thereby yields source and drain electrodes 33.

Next, a gate formation area is opened according to a conventional photolithographic procedure and dielectric film etching procedure. The n-type InGaAs ohmic contact layer 31 in the gate formation area is then removed by recessing and etching to expose the undoped InP layer 30.

On the exposed undoped InP layer 30 are sequentially formed and lifted off a 5-nm Zn layer, a 20-nm Ta layer, a 20-nm Pt layer, a 50-nm Ti layer, a 50-nm Pt layer, and a 500-nm Au layer in this order according to a conventional EB vapor deposition procedure and lifting off procedure. The resulting assemblage is annealed at 350° C. in an atmosphere of nitrogen gas and thereby yields a gate electrode 35 having a p-type layer 34 formed by diffusion of Zn into the outermost surface of the semiconductor underneath the gate, to thereby yield the InAlAs/InGaAs strain relaxation element 41 having a sectional structure shown in FIG. 3.

The InAlAs/InGaAs strain relaxation HEMT 41 prepared according to the present embodiment comprises the InP layer 30 as an In-containing compound semiconductor and the Schottky electrode (gate electrode) 35 arranged on the InP layer 30. The Schottky electrode 35 comprises an assemblage of the Zn diffused layer as a thin p-type dopant-containing layer, the Ta layer as a high-melting metal layer arranged on the Zn diffused layer, and the Pt/Ti/Pt/Au layers as a low-resistance conductor layer arranged on the Ta layer.

Although the strain relaxation HEMT 41 according to the present embodiment has the gate electrode 35 arranged on the InP layer 30 having a band gap narrower than InAlAs, the Zn diffused layer 34 is further activated and the strain relaxation HEMT 41 yields a Schottky barrier φb of 0.80 eV higher than the HEMT according to First Embodiment, since the strain relaxation HEMT has been annealed at a higher temperature than that in First Embodiment.

The low-resistance conductor layer of the gate electrode is not specifically limited to the Ti/Pt/Au layer and Pt/Ti/Pt/Au layer, respectively exemplified in First and Second Embodiments, and also includes a Mo/Au layer, Pt/Au layer, Mo/Ti/Pt/Au layer, Ti/Al layer, Mo/Al layer, and other layers.

The p-type dopant-containing layer as a first layer of the gate electrode on the In-containing compound semiconductor is not specifically limited to elementary Zn as exemplified in First and Second Embodiments and also includes, for example, compounds between Zn and elements constituting the In-containing compound semiconductor, such as Ga, Al, As, and P; and alloys of Zn and Ta to yield the same advantages as in the use of Zn alone.

Likewise, the high-melting metal layer as a second layer of the gate electrode is not specifically limited to elementary Ta and also includes intermetallic compounds between Ta and elements constituting the In-containing compound semiconductor, such as Ga, Al, As, and P; and alloys of Ta and Zn to yield the same advantages as in the use of Ta alone.

Third Embodiment

FIG. 4 is a schematic sectional view of a microstrip monolithic microwave integrated circuit (MMIC) 48 as a third embodiment of the present invention.

The monolithic microwave integrated circuit 48 comprises a GaAs substrate 40 and an assemblage arranged on a surface of the GaAs substrate 40. The assemblage comprises a strain relaxation HEMT 41, a resistor 42, a capacitor 43 (including a conductor 44 of a transmission line as an electrode and a capacitor dielectric film 43a), an inductor 45, the conductor 44 of the transmission line, and other microwave circuit elements. The MMIC 48 also comprises a via hole 46 and a grounding conductor 47 on the backside of the GaAs substrate 40. The strain relaxation HEMT 41 used herein is the strain relaxation HEMT having the Schottky electrode according to Second Embodiment of the present invention.

Fourth Embodiment

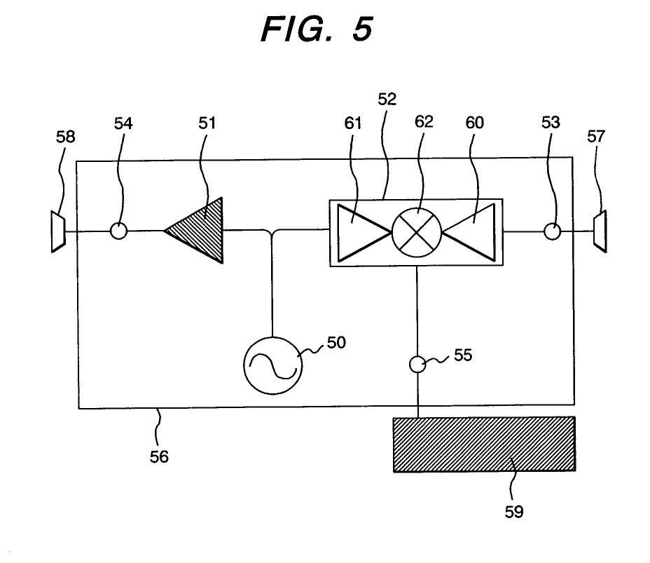

FIG. 5 is a schematic circuit diagram of a vehicle-mounted radar as a fourth embodiment of the present invention. The vehicle-mounted radar includes a high frequency module 56 comprising a voltage controlled oscillator 50, an amplifier 51, a receiver 52, a receiving antenna terminal 53, a transmitting antenna terminal 54, and a terminal 55. The vehicle-mounted radar also includes a receiving antenna 57 connected to the receiving antenna terminal 53; a transmitting antenna 58 connected to the transmitting antenna terminal 54; and a signal processing system 59 connected to the terminal 55. The voltage controlled oscillator 50, the amplifier 51 and the receiver 52 are each the MMIC 48 according to Third Embodiment. The receiver 52 includes amplifiers 60 and 61 and a mixer 62.

The operation of the vehicle-mounted radar will be described below. A signal at 76 GHz from the voltage controlled oscillator 50 is amplified by the amplifier 51 and is radiated via the transmitting antenna terminal 54 from the transmitting antenna 58. The signal reflected from an object is received by the receiving antenna 57, is transported via the receiving antenna terminal 53 and is amplified by the amplifier 60 of the receiver 52.

The amplified signal is then mixed with a reference signal at 76 GHz in the mixer 62 of the receiver 52 to yield an intermediate frequency (IF) signal. The reference signal is from the voltage controlled oscillator 50 and is amplified by the amplifier 61 of the receiver 52. The IF signal is output from the terminal 55 and enters the signal processing system 59 to thereby determine the relative speed, distance, and angle of the object by calculation.

The high frequency module of the present embodiment uses the MMIC 48 according to Third Embodiment and can thereby yield a high-performance and high-reliability vehicle-mounted radar.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

What is claimed is:

1. A compound semiconductor device comprising:
a compound semiconductor substrate;
an In-containing compound semiconductor arranged on the compound semiconductor substrate; and
a Schottky electrode arranged on the In-containing compound semiconductor,
the Schottky electrode comprising:
a p-type dopant-containing layer being in contact with the In-containing compound semiconductor;
a high-melting metal layer arranged on the p-type dopant-containing layer; and
a low-resistance conductor layer arranged on the high-melting metal layer.

2. The compound semiconductor device according to claim 1, wherein the p-type dopant-containing layer is a film comprising a p-type dopant material selected from the group consisting of Zn, intermetallic compounds between Zn and an element constituting the In-containing compound semiconductor, and Zn—Ta alloys.

3. The compound semiconductor device according to claim 1, wherein the high-melting metal layer is a film comprising a metallic material selected from the group consisting of Ta, intermetallic compounds between Ta and an element constituting the In-containing compound semiconductor, and Zn—Ta alloys.

4. The compound semiconductor device according to claim 1, wherein the low-resistance conductor layer is one selected from the group consisting of a Au single-layer film, an Al single-layer film, a metallic multilayer film having Au as the uppermost layer, and a metallic multilayer film having Al as the uppermost layer.

5. The compound semiconductor device according to claim 1, wherein the p-type dopant-containing layer has a thickness from 1 nm to 50 nm.

6. The compound semiconductor device according to claim 1, wherein the high-melting metal layer has a thickness from 1 nm to 50 nm.

7. The compound semiconductor device according to claim 1, which is a field-effect transistor having the Schottky electrode as a gate electrode.

8. The compound semiconductor device according to claim 1, which is a microwave integrated circuit having a field-effect transistor, wherein the field-effect electrode comprises the Schottky electrode as a gate electrode

9. A high frequency module comprising:
a voltage controlled oscillator;
a transmitting antenna terminal;
an amplifier connected between the voltage controlled oscillator and the transmitting antenna terminal;
a receiving antenna terminal;
a receiver connected between the voltage controlled oscillator and the receiving antenna terminal, the receiver having a mixer; and
a terminal for intermediate frequency signals from the mixer of the receiver,
wherein the voltage controlled oscillator, the amplifier, and the receiver are each a microwave integrated circuit comprising the compound semiconductor device of claim 8.

10. A vehicle-mounted radar comprising:
the high frequency module of claim 9;
a receiving antenna connected to the receiving antenna terminal of the high frequency module;
a transmitting antenna connected to the transmitting antenna terminal of the high frequency module; and
a signal processing system connected to the terminal for intermediate frequency signals of the high frequency module.

11. A method for producing a compound semiconductor device, comprising at least the steps of:
sequentially forming, on a desired region of an In-containing compound semiconductor, a p-type dopant-containing layer comprising a material capable of forming Schottky contact with the desired region, a high-melting metal layer, a low-resistance conductor layer in this order to thereby form a metallic multilayer film; and
subjecting the metallic multilayer film to a heat treatment.
